(19) United States
(12) Patent Application Publication
(10) Pub. No.: US 2024/0321353 A1
(43) Pub. Date: Sep. 26, 2024

(54) Non-Volatile Memory Circuit with Self-Terminating Read Current

(71) Applicant: Board of Regents, The University of Texas System, Austin, TX (US)

(72) Inventors: Naimul Hassan, Dallas, TX (US); Alexander J. Edwards, Melissa, TX (US); Disha Biswas, Dallas, TX (US); Georgios Makris, Dallas, TX (US); Joseph S. Friedman, Dallas, TX (US)

(21) Appl. No.: 18/611,468

(22) Filed: Mar. 20, 2024

Related U.S. Application Data
(60) Provisional application No. 63/491,298, filed on Mar. 21, 2023.

(51) Int. Cl. G11C 13/00

(52) U.S. Cl. CPC G11C 13/004; G11C 13/0069

(57) ABSTRACT

A non-volatile memory circuit includes a first transistor which has a first terminal coupled to a DC voltage supply and has a second terminal and a gate. The memory circuit includes a second transistor which has a first terminal coupled to a reference potential, a second terminal and a gate coupled to the gate of the first transistor. The memory circuit includes a memory resistor circuit which has a first terminal coupled to the second terminal of the first transistor, a second terminal coupled to the second terminal of the second transistor and has a third terminal. The memory circuit includes an inverter which has a first terminal coupled to the DC voltage supply, a second terminal coupled to the reference potential and a third terminal coupled to the third terminal of the memory resistor circuit.

### CROSS REFERENCE TO RELATED APPLICATION

This application claims priority from U.S. Provisional Application No. 63/491,298, filed Mar. 21, 2023, entitled “NON-VOLATILE MEMORY CIRCUIT WITH AUTOMATIC SELF-TERMINATING READ” assigned to the present assignee and incorporated herein by reference.

### BACKGROUND

The disclosure generally relates to non-volatile memory, and more specifically to a non-volatile memory circuit with self-terminating read current.

### DESCRIPTION OF THE RELATED ART

Conventional circuits employed for reading non-volatile memory exhibit inherent limitations, primarily characterized by constant current flow and high power dissipation during a read cycle. This presents a significant drawback as it impedes the continuous reading of non-volatile memory with an energy efficiency comparable to static random access memory (SRAM). The conventional circuits for reading the resistance of non-volatile memory devices rely on voltage divider circuits, necessitating constant current flow and causing substantial power dissipation. Consequently, these conventional circuits fail to harness the benefits of non-volatility while maintaining continuous cell state presentation.

### SUMMARY

An illustrative embodiment provides a non-volatile memory circuit. The memory circuit includes a first PMOS transistor which has a source coupled to a DC voltage supply and has a gate and a drain. The memory circuit includes a first NMOS transistor which has a source coupled to a reference potential, a gate coupled to the gate of the first PMOS transistor and has a drain. The memory circuit includes a first memory resistor which has a first terminal coupled to the drain of the first PMOS transistor and has a second terminal. The memory circuit includes a second memory resistor which has a first terminal coupled to the drain of the first NMOS transistor and has a second terminal coupled to the second terminal of the first memory resistor. The memory circuit includes a second PMOS transistor which has a source coupled to the DC voltage supply, a gate coupled to the second terminals of the first and second memory resistors, and has a drain. The memory circuit includes a second NMOS transistor which has a drain coupled to the drain of the second PMOS transistor, a gate coupled to the second terminals of the first and second memory resistors, and has a source coupled to the reference potential. The drains of the second PMOS and NMOS transistors are coupled to the gates of the first PMOS and NMOS transistors.

In an illustrative embodiment, the memory circuit includes a fifth transistor which has a first terminal coupled to receive an input signal, a second terminal coupled to the drain of the first PMOS transistor and a gate coupled to receive a write enable signal. The memory circuit includes a sixth transistor which has a first terminal coupled to the drain of the first NMOS transistor, a second terminal coupled to the reference potential and a gate coupled to the receive the write enable signal. The memory circuit includes a feedback loop formed by a connection between the drains of the second PMOS and NMOS transistors and the gates of the first PMOS and NMOS transistors.

In an illustrative embodiment, a non-volatile memory circuit includes a first transistor which has a first terminal coupled to a DC voltage supply and has a second terminal and a gate. The memory circuit includes a second transistor which has a first terminal coupled to a reference potential, a second terminal, and a gate coupled to the gate of the first transistor. The memory circuit includes a memory resistor circuit which has a first terminal coupled to the second terminal of the first transistor, a second terminal coupled to the second terminal of the second transistor, and has a third terminal. The memory circuit includes an inverter which has a first terminal coupled to the DC voltage supply, a second terminal coupled to the reference potential and a third terminal coupled to the third terminal of the memory resistor circuit.

### BRIEF DESCRIPTION OF THE DRAWINGS

FIG. 1 is a schematic of a non-volatile memory circuit in accordance with an illustrative embodiment;

FIG. 2 is a detailed schematic of a non-volatile memory circuit 200 in accordance with an illustrative embodiment;

FIG. 3 illustrates various waveforms generated in the memory circuit of FIG. 2 during write and read operations;

FIG. 4 illustrates a memory device having a plurality of memory cells in accordance with an illustrative embodiment;

FIG. 5 is a schematic of a non-volatile memory circuit in accordance with another illustrative embodiment; and

FIG. 6 illustrates a memory device in accordance with another illustrative embodiment.

### DETAILED DESCRIPTION

Reference will now be made in detail to the embodiments, examples of which are illustrated in the accompanying drawings, in which some, but not all embodiments are shown. Indeed, the concepts may be embodied in many different forms and should not be construed as limiting herein. Rather, these descriptions are provided so that this disclosure will satisfy applicable requirements.

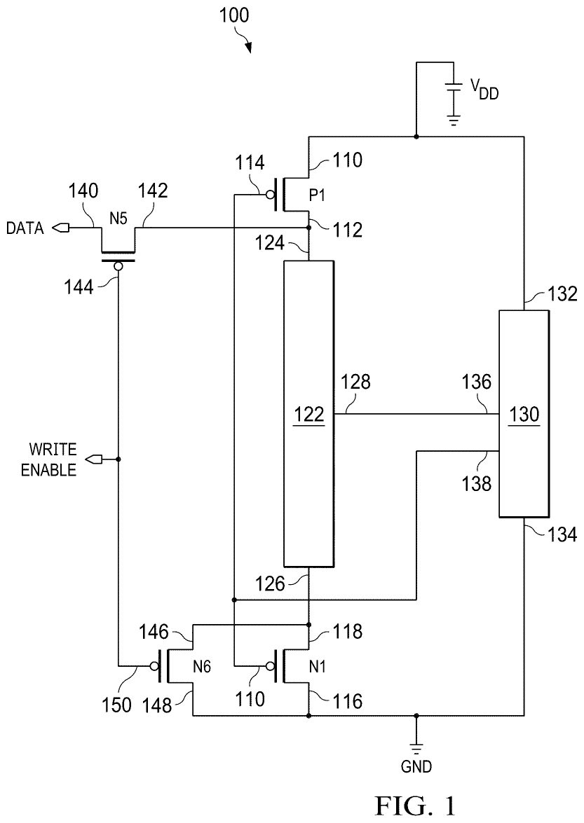

FIG. 1 is a schematic of non-volatile memory circuit 100 in accordance with an illustrative embodiment. Memory circuit 100 is configured to continuously present a stored non-volatile state (e.g., binary bit “1” or binary bit “0”) to an output, requiring minimal overhead circuitry and power consumption.

With reference to FIG. 1, memory circuit 100 includes first transistor P1 which has first terminal 110 coupled to DC voltage supply V_{DD} (e.g., 0.8V or 3.5V) and has second terminal 112 and gate 114. In an example embodiment, P1 is a PMOS transistor, first terminal 110 of P1 is a source and second terminal 112 of P1 is a drain.

Memory circuit 100 includes second transistor N1 which has first terminal 116 coupled to reference potential GND, second terminal 118, and has gate 120 coupled to gate 114 of first transistor P1. In an example embodiment, N1 is an NMOS transistor, first terminal 116 of N1 is a source and second terminal 118 of N1 is a drain.

Memory circuit 100 includes memory resistor circuit 122 which has first terminal 124 coupled to second terminal 112 of first transistor P1, second terminal 126 coupled to second terminal 118 of second transistor N1 and has third terminal 128.

Memory circuit 100 includes inverter 130 which has first terminal 132 coupled to DC voltage supply V_{DD}, second terminal 134 coupled to reference potential GND, third terminal 136 coupled to third terminal 128 of memory resistor circuit 122, and fourth terminal 138 coupled to gates 114 and 120 of transistors P1 and N1, respectively.

Memory circuit 100 includes transistor N5 (also referred herein as input transistor) which has first terminal 140 coupled to receive an input signal (also referred as DATA), second terminal 142 coupled to second terminal 112 of first transistor P1 and gate 144 coupled to receive WRITE_ENABLE signal. Memory circuit 100 includes transistor N6 (also referred herein as write enable transistor) which has first terminal 146 coupled to second terminal 118 of second transistor N1, second terminal 148 coupled to reference potential GND and gate 150 coupled to receive the write enable signal.

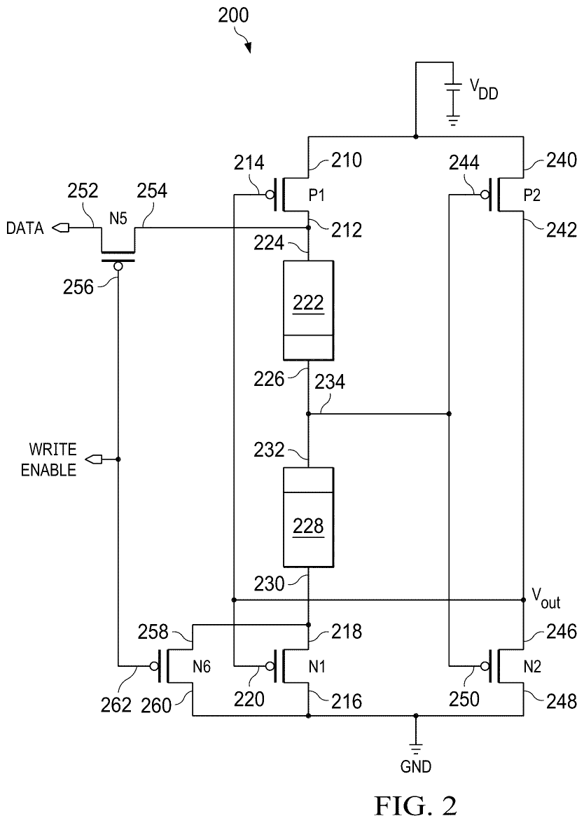

FIG. 2 is a detailed schematic of non-volatile memory circuit 200 in accordance with an illustrative embodiment. Memory circuit 200 includes a first PMOS transistor P1 which has source 210 coupled to DC voltage supply V_{DD} and has drain 212 and gate 214. Memory circuit 200 includes first NMOS transistor N1 which has source 216 coupled to reference potential GND, drain 218, and gate 220 coupled to gate 214 of first PMOS transistor P1.

Memory circuit 200 includes first memory resistor 222 which has first terminal 224 coupled to drain 212 of first PMOS transistor P1 and has second terminal 226. Memory circuit 200 includes second memory resistor 228 which has first terminal 230 coupled to drain 218 of first NMOS transistor N1 and has second terminal 232 coupled to second terminal 226 of first memory resistor 222. First and second memory resistors 222 and 228 form a voltage divider at interconnection junction 234.

Memory circuit 200 includes second PMOS transistor P2 which has source 240 coupled to DC voltage supply V_{DD}, drain 242, and gate 244 coupled to second terminals 226 and 232 of first and second memory resistors 222 and 228. Memory circuit 200 includes second NMOS transistor N2 which has drain 246 coupled to drain 242 of second PMOS transistor P2, source 248 coupled to reference potential GND, and gate 250 coupled to second terminals 226 and 232 of respective first and second memory resistors 222 and 228. Drains 242 and 246 of respective second PMOS and NMOS transistors 242 and 246 are coupled to gates 214 and 220 of respective first PMOS and first NMOS transistors P1 and N1. Thus, a feedback loop is established between second transistors P2 and N2 and first transistors P1 and N1. Memory circuit 200 provides output V_{OUT} at drains 242 and 246 of transistors P2 and N2.

Memory circuit 200 includes fifth transistor N5 which has first terminal 252 coupled to receive an input signal (also referred to as DATA), second terminal 254 coupled to drain 224 of first PMOS transistor P1, and gate 256 coupled to receive WRITE_ENABLE signal. Memory circuit 200 includes sixth transistor N6 which has first terminal 258 coupled to drain 218 of first NMOS transistor N1, second terminal 260 coupled to reference potential GND and gate 262 coupled to the receive the WRITE_ENABLE signal. In some example embodiments, fifth and sixth transistors N5 and N6 are NMOS transistors.

In some example embodiments, first and second memory resistors 222 and 228 are non-volatile memory resistive devices such as, for example, memristors, phase-change memory or magnetic tunnel junction. First and second memory resistors 222 and 228 acquire a first resistive state if a current flows through memory resistors 222 and 228 in a first direction. First and second memory resistors 222 and 228 acquire a second resistive state if a current flows through memory resistors 222 and 228 in a second direction. In some example embodiments, HRS can, for example, be around 30 k Ohms and LRS can be around 10 k Ohms. Memory resistors 222 and 228 generally store or retain their respective acquired resistive states until they are reprogrammed.

As illustrated in FIG. 2, first and second memory resistors 222 and 228 are connected back-to-back such that if a current flows through memory resistors 222 and 228, they acquire different or opposite resistive states. For example, if a current flows from transistor N5 through first memory resistor 222 and through second memory resistor 228 and then through transistor N6 into reference potential GND, first memory resistor 222 may acquire a low resistive state (e.g., 10 k Ohms) and second memory resistor 228 may acquire a high resistive state (e.g., 30 k Ohms). If the direction of the current flow is reversed, first memory resistor 222 may acquire HRS and second memory resistor 228 may acquire LRS.

The operation of the non-volatile memory circuit is now described with reference to FIG. 2. During a write operation, memory circuit 200 is programmed to store a binary bit “1” or a binary bit “0.” During a read operation, the stored binary bit is provided at output V_{OUT}.

During the write operation, V_{DD} (e.g., 0.8V or 3.5V) is enabled and WRITE_ENABLE signal is asserted at gates 256 and 262 of transistors N5 and N6. As a result, transistors N5 and N6 are turned ON. The input signal (e.g., DATA) is then applied at second terminal 252 of transistor N5. If the input signal is a positive voltage (e.g., +0.8 V or +2.5 V), a current flows through transistor N5, through memory resistors 222 and 228 and then through transistor N6 into reference potential GND. As a result, first memory resistor 222 acquires LRS and second memory resistor 228 acquires HRS.

If the input signal is a negative voltage (e.g., −0.8V or −2.5V), the direction of the current flow is reversed. The current flows from reference potential GND through transistor N6 and through memory resistors 228 and 222 and then out of transistor N5. As a result, memory resistor 228 acquires LRS and memory resistor 222 acquires HRS. Although first PMOS transistor P1 and first NMOS transistor N1 both weakly conduct during the write operation, the input signal applied to first terminal 252 of transistor N5 is much greater relative to the voltage at drain 224 of PMOS transistor P1. As such, the input signal forces memory resistors 222 and 228 to be set or programmed to the desired resistive states.

During the read operation, WRITE_ENABLE signal is de-asserted, the input signal is removed and V_{DD} is applied. As a result, a current flows through first PMOS transistor P1 and through first and second memory resistors 222 and 228 and through first NMOS transistor N1 into reference potential GND. If second memory resistor 228 is set at LRS during the write operation, a low voltage is generated across second memory resistor 228 during the read operation. As a result, the low voltage is applied to gates 244 and 250 of PMOS transistor P2 and NMOS transistor N2, respectively. Thus, PMOS transistor P2 is turned ON while NMOS transistor N2 is turned OFF, causing output voltage Vout to be pulled higher to V_{DD}. When Vout is pulled high to V_{DD}, Vout represents a binary bit “1.”

If, however, second memory resistor 228 is set at HRS during the write cycle, a high voltage is generated across second memory resistor 228. As a result, the high voltage is applied to gates 244 and 250 of PMOS transistor P2 and NMOS transistor N2, respectively. Thus, PMOS transistor P2 is turned OFF while NMOS transistor N2 is turned ON, causing the output voltage Vout to be pulled lower to reference potential GND. When Vout is pulled low to GND, Vout represents a binary bit “0.”

Thus, transistors P2 and N2 act as an inverter which provides Vout which has an inverse relation to the voltage at interconnection junction 234. Furthermore, Vout is fed back to gates 214 and 220 of respective transistors P1 and N1 via the feedback loop. As such, depending on the polarity of Vout, either transistor P1 or transistor N1 is turned OFF, thereby limiting current flow through memory resistors 222 and 228 to a low level (e.g., leakage current through transistors P1 or N1).

Also, as V_{DD} approaches 0.8V, PMOS transistors P1 and P2 operate in saturation regions, causing current flow through transistors P1 and P2 to not rise further. As such, the current through first and second memory resistors 222 and 228 are limited to a low level. However, the output voltage Vout is latched and is continuously provided at drains 242 and 246 of transistors P2 and N2, respectively. When V_{DD} is removed, memory circuit 200 retains the stored bit. When V_{DD} is restored, the stored bit is recovered and provided at Vout.

A key advantage of memory circuit 200 is self-terminating read current characteristics. During the read operation, because the current flow through memory resistors 222 and 228 are held at a low level, power consumption is minimized. As a result, memory circuit 200 exhibits lower power consumption during the read cycle while being non-volatile.

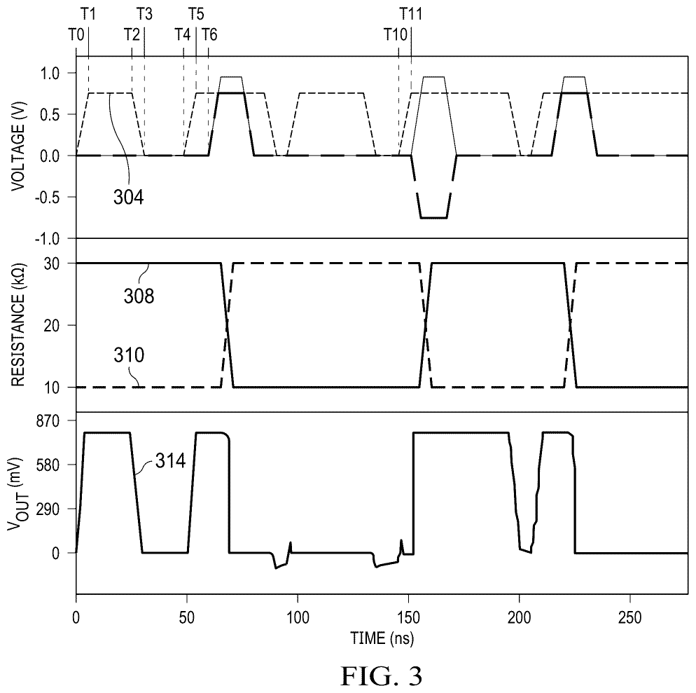

FIG. 3 illustrates various waveforms generated in memory circuit 200 during write and read operations. During a read cycle, at time T0, V_{DD} 304 is applied, and at time T1, V_{DD} 304 rises to 0.8 V. Initially, at time T0, memory resistor 308 is at HRS (e.g., 30 k Ohms) and memory resistor 310 is at LRS (e.g., 10 k Ohms). Memory resistors 308 and 310 correspond to memory resistors 222 and 228, respectively, of FIG. 2. Thus, Vout 314 rises to around 0.8 V, which represents a binary bit “1.” At time T2, V_{DD} is removed and falls to 0 V at time T3. As a result, Vout 314 drops to 0 V, which represents a binary bit “0.” After V_{DD} is removed at time T3, memory resistors 308 and 310 continue to retain their respective resistive states.

During a write cycle, at time T4, V_{DD} 304 is applied. V_{DD} rises to 0.8 V at time T5. Thus, Vout 314 rises up to 0.8 V. At time T6, WRITE_ENABLE 316 is asserted. Also, at time T6, input signal (DATA) 318 is applied which rises from 0 V to 1.0 V. As a result, memory resistor 308 acquires LRS (e.g., 10 k Ohms) and memory resistor 310 acquires HRS (e.g., 30 k Ohms). Thus, in response to a positive input signal, memory resistor 308 acquires LRS (e.g., 10 k Ohms) and memory resistor 310 acquires HRS (e.g., 30 k Ohms).

During the write cycle, when a negative input voltage is applied, memory resistors 308 and 310 reverse their respective resistive states. At time T10, V_{DD} is applied, and at time T11, WRITE_ENABLE 316 is asserted and input voltage is applied. Since the input voltage is negative, memory resistor 308 acquires HRS and memory resistor 310 acquires LRS. As a result, Vout rises up to 0.8 V which correspond to a binary bit “1.”

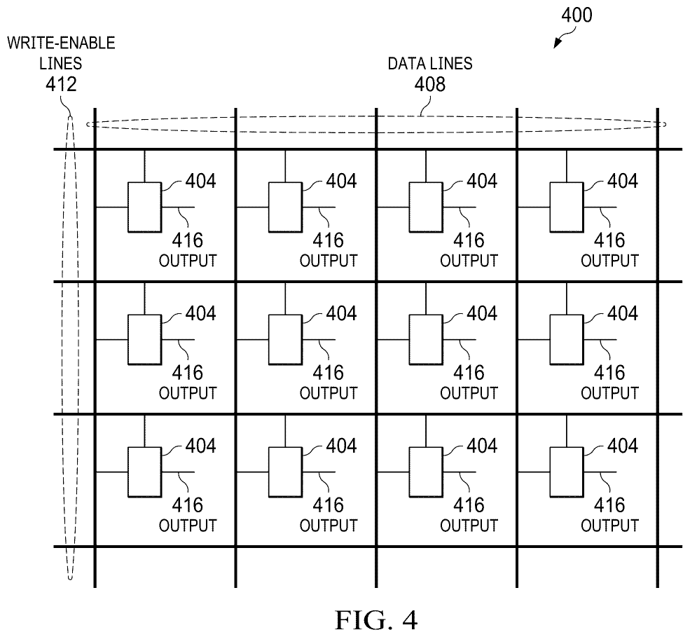

FIG. 4 illustrates a memory device 400 in accordance with an illustrative embodiment. Memory device 400 includes a plurality of memory cells 404 connected in an array. Memory cells 404 are each implemented as memory circuit 200 illustrated in FIG. 2.

Memory device 400 includes a plurality of DATA lines 408, WRITE-ENABLE lines 412 (also referred to as word lines) and OUTPUT lines 416. Each memory cell 404 includes a first terminal coupled to one of DATA lines 408 and includes a second terminal coupled to one of WRITE_ENABLE lines 412. Also, each memory cell 404 includes an output terminal coupled to one of OUTPUT lines 416.

During a write operation, memory cells 404 of memory device 400 are set or programmed to store a binary bit by asserting WRITE_ENABLE signal at lines 412 and applying an input signal at lines 408. During a read operation, the stored binary bit is provided at OUTPUT lines 416.

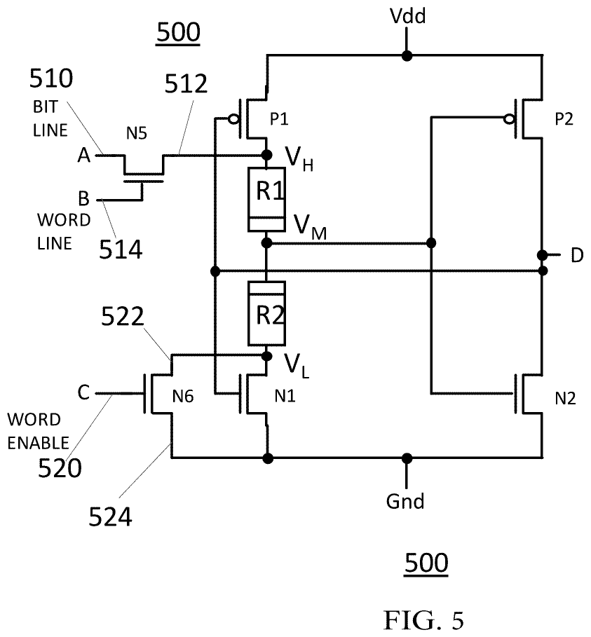

FIG. 5 is a schematic of non-volatile memory circuit 500 in accordance with another illustrative embodiment. Memory circuit 500 is configured to continuously present a stored non-volatile state (e.g., binary bit “1” or binary bit “0”) to an output, requiring minimal overhead circuitry and power consumption.

Memory circuit 500 includes PMOS transistors P1, P2, NMOS transistors N1, N2, N5, N6, and memory resistors R1 and R2. NMOS Transistor N5 has first terminal 510 coupled to receive input signal A, second terminal 512 coupled to memory resistor R1 and PMOS transistor P1, and gate 514 coupled to receive signal B. NMOS transistor N6 has gate 520 coupled to receive signal C (enable signal), first terminal 522 coupled to memory resistor R2 and NMOS transistor N1, and second terminal 524 coupled to reference potential GND.

During the write operation, V_{DD} (e.g., 0.8V or 2.5V) is enabled and signals B and C are asserted at gates 514 and 520 of respective transistors NMOS N5 and N6. As a result, transistors N5 and N6 are turned ON. Input signal A is then applied at terminal 510 of transistor N5. If the input signal is a positive voltage (e.g., +0.8 V or +2.5V), a current flows through transistor N5, through memory resistors R1 and R2 and then through transistor N6 into reference potential GND. As a result, memory resistor R1 acquires LRS and memory resistor R2 acquires HRS.

If the input signal A is a negative voltage (e.g., −0.8V or −2.5V), the direction of the current flow is reversed. The current flows from reference potential GND through transistor N6 and through memory resistors R2 and R1 and then out of transistor N5. As a result, memory resistor R2 acquires LRS and memory resistor R1 acquires HRS. Turning on N6 causes node VM to fall, causing the inverter formed by P2 and N2 raise output D to a high voltage, turning off P1, and allowing VH to be driven solely by input signal A, and as such, the input signal forces memory resistors R1 and R2 to be set or programmed to the desired resistive states.

During the restore operation, signals B and C are de-asserted, input signal A is removed and V_{DD} rises from 0V to the final DC supply voltage. As a result, a small current flows through transistor P1 and through first and second memory resistors R1 and R2 and through transistor N1 into reference potential GND. If the memory resistor R1 is set at HRS and the memory resistor R2 is set at LRS during the write operation, a low voltage is generated across memory resistor R2 during the read operation. As a result, the low voltage is applied to gates of transistor P2 and transistor N2. Thus, transistor P2 is turned ON while transistor N2 is turned OFF, causing output voltage D to be pulled higher to V_{DD}. When D is pulled high to V_{DD}, D represents a binary bit “1.”

If, however, memory resistor R1 is set at LRS and memory resistor R2 is set at HRS during the write cycle, a high voltage is generated across memory resistor R2. As a result, the high voltage is applied to gates of PMOS transistor P2 and NMOS transistor N2, respectively. Thus, PMOS transistor P2 is turned OFF while NMOS transistor N2 is turned ON, causing the output D to be pulled lower to reference potential GND. When D is pulled low to GND, D represents a binary bit “0.”

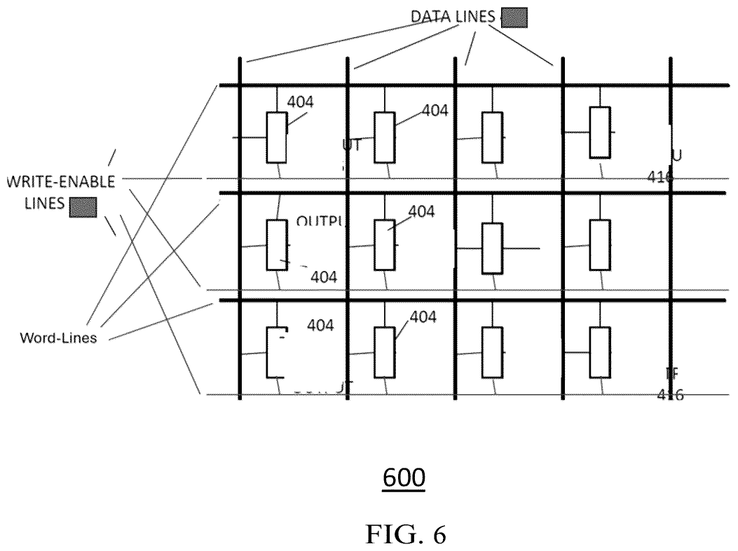

FIG. 6 illustrates a memory device 600 in accordance with another illustrative embodiment. Memory device 600 includes a plurality of memory cells 404 connected in an array

Memory device 600 includes a plurality of BIT-LINEs, WORD-LINEs, and WRITE-ENABLE lines. Each memory cell 404 includes a first terminal coupled to one of the BIT-LINEs, a second terminal coupled to one of the WORD-LINES, and a third terminal coupled to one of the WRITE_ENABLE lines.

During a write operation, memory cells 404 of memory device 600 are set or programmed to store a binary bit by asserting WRITE_ENABLE and WORD-LINE signals and applying data at all of the BIT-LINES simultaneously. During a read operation, a specific word is read by precharging all of the BIT-LINES, asserting the chosen WORD-LINE, and sensing the charge remaining on the BIT-LINES.

In some example embodiments, a non-volatile memory circuit has a binary memory state appearing at a bit cell output and a self-terminating read current to read the binary memory state. The non-volatile memory circuit is configured to provide a constant presentation of the memory state. The memory state is non-volatile and can be repeatedly written to a 0 or 1 value. The read current operatively latches the binary memory state on the initial presence of a sufficient supply voltage. The read current is automatically eliminated upon latching the binary memory state. The memory circuit is robust to power cycling and discontinuity of the read current. In some example embodiments, an array of non-volatile memory circuits include an array of bit cell outputs which are connected to program bits of a field programmable gate array. The array of memory circuits can be incorporated within an SRAM array. Upon application of the supply voltage, the SRAM array automatically restores the data stored before the supply voltage was removed.

Various illustrative components, blocks, modules, circuits, and steps have been described above in general terms of their functionality. Whether such functionality is implemented as hardware or software depends upon the particular application and design constraints imposed on the overall system. The described functionality may be implemented in varying ways for each particular application, but such implementation decision should not be interpreted as causing a departure from the scope of the present disclosure.

For simplicity and clarity, the full structure and operation of all systems suitable for use with the present disclosure is not being depicted or described herein. Instead, only so much of a system as is unique to the present disclosure or necessary for an understanding of the present disclosure is depicted and described.

What is claimed is:

1. A non-volatile memory circuit, comprising:
a first PMOS transistor having a source coupled to a DC voltage supply and having a gate and a drain;
a first NMOS transistor having a source coupled to a reference potential, a gate coupled to the gate of the first PMOS transistor and having a drain;
a first memory resistor having a first terminal coupled to the drain of the first PMOS transistor and having a second terminal;
a second memory resistor having a first terminal coupled to the drain of the first NMOS transistor and having a second terminal coupled to the second terminal of the first memory resistor;
a second PMOS transistor having a source coupled to the DC voltage supply, a gate coupled to the second terminals of the first and second memory resistors, and having a drain; and
a second NMOS transistor having a drain coupled to the drain of the second PMOS transistor, a gate coupled to the second terminals of the first and second memory resistors, and having a source coupled to the reference potential; and
wherein the drains of the second PMOS and NMOS transistors are coupled to the gates of the first PMOS and NMOS transistors.

2. The memory circuit of claim 1, further comprising:
a fifth transistor having a first terminal coupled to receive an input signal, a second terminal coupled to the drain of the first PMOS transistor and a gate coupled to receive a write enable signal; and
a sixth transistor having a first terminal coupled to the drain of the first NMOS transistor, a second terminal coupled to the reference potential and a gate coupled to the receive the write enable signal.

3. The memory circuit of claim 1, further comprising a feedback loop formed by a connection between the drains of the second PMOS and NMOS transistors and the gates of the first PMOS and NMOS transistors.

4. The memory circuit of claim 2, wherein the first memory resistor acquires a high resistive state and the second memory resistor acquires a low resistive state in response to a current driven by the fifth transistor through the first memory resistor and through the second memory resistor and through the sixth transistor into the reference potential.

5. The memory circuit of claim 2, wherein the second memory resistor acquires a high resistive state and the first memory resistor acquires a low resistive state value in response to a current drawn by the fifth transistor through the first memory resistor, wherein the current flows from the reference potential through the sixth transistor and through the second and first memory resistors.

6. The memory circuit of claim 2, wherein in a write cycle, the input signal is enabled and the write enable signal is asserted, causing the fifth and sixth transistors to turn ON.

7. The memory circuit of claim 2, wherein in a write cycle, the first memory resistor acquires a high resistive state and the second memory resistor acquires a low resistive state responsive to the input signal being a positive voltage.

8. The memory circuit of claim 2, wherein in a write cycle, the second memory resistor acquires a high resistive state and the first memory resistor acquires a low resistive state responsive to the input signal being a negative voltage.

9. The memory circuit of claim 2, wherein in a read cycle, the input signal is disabled and the write enable signal is de-asserted, causing the fifth and sixth transistors to turn OFF.

10. The memory circuit of claim 2, wherein in a read cycle, a current flows from the DC voltage supply through the first PMOS transistor and through the first and second memory resistors and through the first NMOS transistor into the reference potential.

11. The memory circuit of claim 2, wherein in a read cycle, a voltage at the second terminals of the first and second memory resistors are inverted by the second PMOS and NMOS transistors and provided as an output voltage at the drains of the second PMOS and NMOS transistors.

12. The memory circuit of claim 11, wherein in a read cycle, the second PMOS transistor is turned OFF and the second NMOS transistor is turned ON responsive to the first memory resistor being in a low resistive state and the second memory resistor being in a high resistive state.

13. The memory circuit of claim 11, wherein in a read cycle, the second PMOS transistor is turned ON and the second NMOS transistor is turned OFF responsive to the first memory resistor being in a high resistive state and the second memory resistor being in a low resistive state.

14. A non-volatile memory circuit, comprising:
a first transistor having a first terminal coupled to a DC voltage supply and having a second terminal and a gate;
a second transistor having first terminal coupled to a reference potential, a second terminal, and a gate coupled to the gate of the first transistor;
a memory resistor circuit having a first terminal coupled to the second terminal of the first transistor, a second terminal coupled to the second terminal of the second transistor, and having a third terminal; and
an inverter having a first terminal coupled to the DC voltage supply, a second terminal coupled to the reference potential and a third terminal coupled to the third terminal of the memory resistor circuit.

15. The memory circuit of claim 14, wherein the memory resistor circuit comprises first and second memory resistors coupled in series between the first and second transistors, wherein the first and second memory resistors are connected at the third terminal.

16. The memory circuit of claim 14, wherein the first transistor is a PMOS transistor, and wherein the first terminal of the PMOS transistor is a source and the second terminal of the PMOS transistor is a drain.

17. The memory circuit of claim 14, wherein the second transistor is an NMOS transistor, and wherein the first terminal of the NMOS transistor is a source and the second terminal of the NMOS transistor is a drain.

18. The memory circuit of claim 15, further comprising:
an input transistor having a first terminal coupled to receive an input signal, a second terminal coupled to the second terminal of the first transistor, and a gate coupled to receive a write enable signal; and
a write enable transistor having a first terminal coupled to the second terminal of the second transistor, a second terminal coupled to the reference potential and a gate coupled to receive the write enable signal.

19. A non-volatile memory device, comprising:
a plurality of data lines;
a plurality of word lines;
a plurality output lines;
a plurality non-volatile memory circuits, wherein each memory circuit comprises:
a first terminal coupled to one of the data lines;
a second terminal coupled to one of the word lines; and
a third terminal coupled to one of the output lines, wherein each non-volatile memory circuit comprises:
a first PMOS transistor having a source coupled to a DC voltage supply and having a gate and a drain;
a first NMOS transistor having a source coupled to a reference potential, a gate coupled to the gate of the first PMOS transistor and having a drain;
a first memory resistor having a first terminal coupled to the drain of the first PMOS transistor and having a second terminal;
a second memory resistor having a first terminal coupled to the drain of the first NMOS transistor and having a second terminal coupled to the second terminal of the first memory resistor;
a second PMOS transistor having a source coupled to the DC voltage supply, a gate coupled to the second terminals of the first and second memory resistors, and having a drain; and
a second NMOS transistor having a drain coupled to the drain of the second PMOS transistor, a gate coupled to the second terminals of the first and second memory resistors, and having a source coupled to the reference potential;
a fifth transistor having a first terminal coupled to one of the data lines, a second terminal coupled to the drain of the first PMOS transistor, and a gate coupled to one of the word lines;
a sixth transistor having a first terminal coupled to the drain of the first NMOS transistor, a second terminal coupled to the reference potential and a gate coupled to one of the word lines; and
wherein the drains of the second PMOS and NMOS transistors are coupled one of the output lines and coupled to the gates of the first PMOS and NMOS transistors.

20. The memory device of claim 19, wherein the fifth transistor is configured to receive an input signal from the data line.

21. The memory device of claim 19, wherein the sixth transistor is configured to receive a word enable signal from the word line.

22. The memory device of claim 19, wherein the fifth and sixth transistors are turned ON during a write cycle.

23. The memory device of claim 19, wherein the fifth and sixth transistors are turned OFF during a read cycle.
